(19) United States
(12) Patent Application Publication
(10) Pub. No.: US 2006/0226549 A1
(43) Pub. Date: Oct. 12, 2006

(54) Semiconductor device and fabricating method thereof

(75) Inventors: Chen-Hua Yu, Keelung City (TW); Yung-Cheng Lu, Taipei (TW); Hui-Lin Chang, Hsinchu City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/104,266

(22) Filed: Apr. 12, 2005

(51) Int. Cl. H01L 23/52; H01L 21/4763

(52) U.S. Cl. 257/760; 257/635; 438/786; 438/624; 438/675

(57) ABSTRACT

A semiconductor device and a fabrication method thereof. The semiconductor device has a substrate with a first conductive area, a dielectric layer formed of a low dielectric constant material disposed on the substrate, and a dielectric anti-reflective coating (DARC) layer disposed on the dielectric layer. A contact hole is disposed in the DARC layer and the dielectric layer to the first conductive area and a contact plug is disposed in the contact hole and electrically connected to the first conductive area.

### BACKGROUND

The invention relates to a semiconductor device and a fabrication method thereof, and more particularly, to a semiconductor device with an interconnect structure and a fabrication method thereof.

As integrated circuits (ICs) are scaled down to the deep submicron level, interconnect delay becomes increasingly dominant over intrinsic gate delay. Two practical methods are popularly employed to address this issue. The first method uses copper as the conductor for multilevel interconnects to decrease the resistance parts of RC delay. The second method employs a low dielectric constant material to reduce a coupling capacitance between metal lines.

Currently, the damascene method is the most widely used method for forming copper interconnects along with low dielectric constant (low-k) dielectric materials in back end of line (BEOL). For example, in a single damascene process for forming the interconnects, at least one dielectric layer, such as a low dielectric constant material, is first deposited on a substrate serving as an interlayer dielectric (ILD) layer or a inter-metal dielectric (IMD) layer. The dielectric layer is patterned using photolithography with trenches, holes, and/or channels. The trenches, holes, and/or channels are filled with a conductive material, such as copper, to form vias, contacts, plugs, and conductive lines within the dielectric layer. A chemical mechanical polish (CMP) process is then performed to remove excess conductive material from over a top surface of the dielectric layer. In addition, the single damascene process mentioned previously can be further modified as a dual damascene process in which a via and a trench are stacked in the dielectric layer. These damascene processes can be repeated to form a multi-layer interconnect structure.

In addition, a plurality of layers are functionally required to improve reliability and accuracy of the damascene process with miniaturization or scaling down of semiconductor device size. For example, during patterning of the dielectric layer, a mask layer is required to define a pattern of the dielectric layer. An etching stop layer is required to control a depth or operation time of an etching process. Again, an anti-reflective coating (ARC) layer is necessary to reduce a reflective rate and improve accuracy of transferring patterns from a photo mask. Thereafter, a CMP stop layer is still required for the CMP process. These functional layers increase the operating costs significantly for a multi-layer interconnect. Thus, an integrated interconnect structure and a fabrication method thereof are desirable to solve the aforementioned problems.

### SUMMARY

An embodiment of a semiconductor device comprises a substrate with a first conductive area, a dielectric layer formed of a low dielectric constant material disposed on the substrate, and a carbon-containing dielectric anti-reflective coating (DARC) layer disposed on the dielectric layer. A contact hole is disposed in the DARC layer and the dielectric layer to the first conductive area and a contact plug is disposed in the contact hole and electrically connected to the first conductive area.

In an exemplary embodiment of a method of fabricating a semiconductor device, a substrate with a first conductive area thereon is first provided. An etching stop layer is formed on the first conductive layer. A dielectric layer comprising a low dielectric constant material is then formed on the substrate. A carbon-containing dielectric anti-reflective coating (DARC) layer is formed on the dielectric layer. The DARC layer is patterned to form a first opening in the DARC layer. An etching process is performed along the first opening to form a contact hole in the dielectric layer and the etching stop layer and expose the first conductive area. A first conductive layer is formed on the DARC layer and filled into the contact hole. The first conductive layer is electrically connected to the first conductive area. Thereafter, a chemical mechanical polishing (CMP) process is performed using the DARC layer as a CMP stop layer to remove the first conductive layer above a top surface of the DARC layer.

### DESCRIPTION OF THE DRAWINGS

The invention can be more fully understood by reading the subsequent detailed description and examples with references made to the accompanying drawings, wherein:

FIGS. 1 to 5 are schematic diagrams of an embodiment of a method of fabricating a semiconductor device; and

FIG. 6 is a schematic diagram of another embodiment of a semiconductor device.

FIG. 7 is a schematic diagram of another embodiment of a semiconductor device

### DETAILED DESCRIPTION

A semiconductor device with an interconnect structure is provided in the invention. As will be described in detail here, some embodiments of a semiconductor device have a contact plug. It is noted that the “contact plug” is offered as an example. In fact, the contact plug can be all kinds of interconnect structures, such as vias, conductive lines, or a combination thereof, such as a dual damascene structure comprising a trench line and a via or multi-layer interconnects comprising aforementioned structures and the contact hole described latter comprises trenches, holes, or channels for accommodating the contact plugs, vias, or conductive lines. In other words, the invention is not limited to a semiconductor with a contact plug, but can be applied to all kinds of semiconductor devices having an interconnect structure since it would be obvious to one of ordinary skill in the art to apply embodiments of the invention to other semiconductor devices with interconnect structures, In addition, descriptions of other parts of semiconductor device are omitted as they are known to those skilled in the art and not directly related.

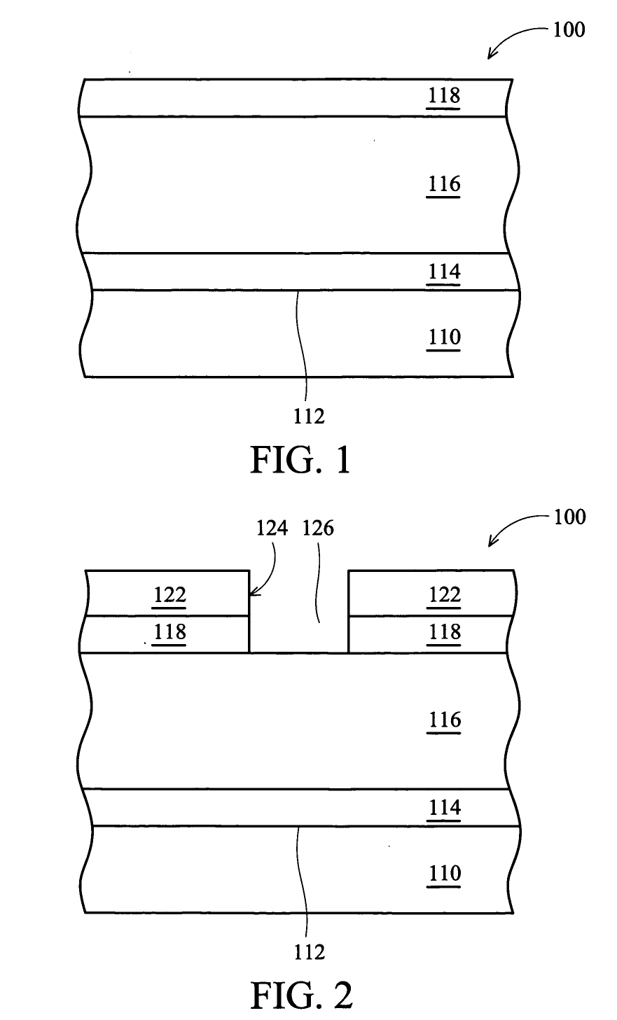

FIGS. 1-5 are schematic diagrams of a method of fabricating a semiconductor device 100 according to an embodiment of the invention. As shown in FIG. 1, a substrate 110 with a first conductive area 112 thereon is provided. The first conductive area 112 may be an electronic device or any conductive feature of an electronic device. An etching stop layer 114 is formed on the substrate 110 covering the first conductive area 112. A dielectric layer 116 is formed on the etching stop layer 114 and a carbon-containing dielectric anti-reflective coating (DARC) layer 118 is then formed on the dielectric layer 116 for reducing a high reflective rate caused by the conductive area 112, thereby improving accuracy of subsequent lithography processes. In addition, the DARC layer 118 further has characteristics of high hardness and a high etching selectivity over the dielectric layer 116.

In an embodiment of the invention, the dielectric layer 116 comprises a low dielectric constant material, such as diamond-like carbon. The DARC layer 118 may be a nitrogen-free DARC (NFDARC) layer which comprises SiC, SiCO, SiCO:H, or a combination thereof. The dielectric layer 116 has a dielectric constant below 3, and preferably below 2.6. In addition, the DARC layer 118 has a dielectric constant of 3 to 5 and an etching selectivity between the DARC layer 118 and the dielectric layer 116 is larger than 5.

As shown in FIG. 2, the DARC layer 118 is patterned to form a first opening 126 in the DARC layer 118. In an embodiment of the invention, a photoresist layer 122 is first formed on the DARC layer 118 and then patterned to form a second opening 124 in the photoresist layer 122 using a lithography process with a wavelength of 248 nm or below, preferably 193 nm or below. As previously mentioned, the DARC layer 118 can reduce a reflective rate of the semiconductor device 100 and improve accuracy of the lithography process. The DARC layer 118 is patterned using an etching process to form the first opening 126 beneath the second opening 122. Thereafter, the photoresist layer 122 is removed.

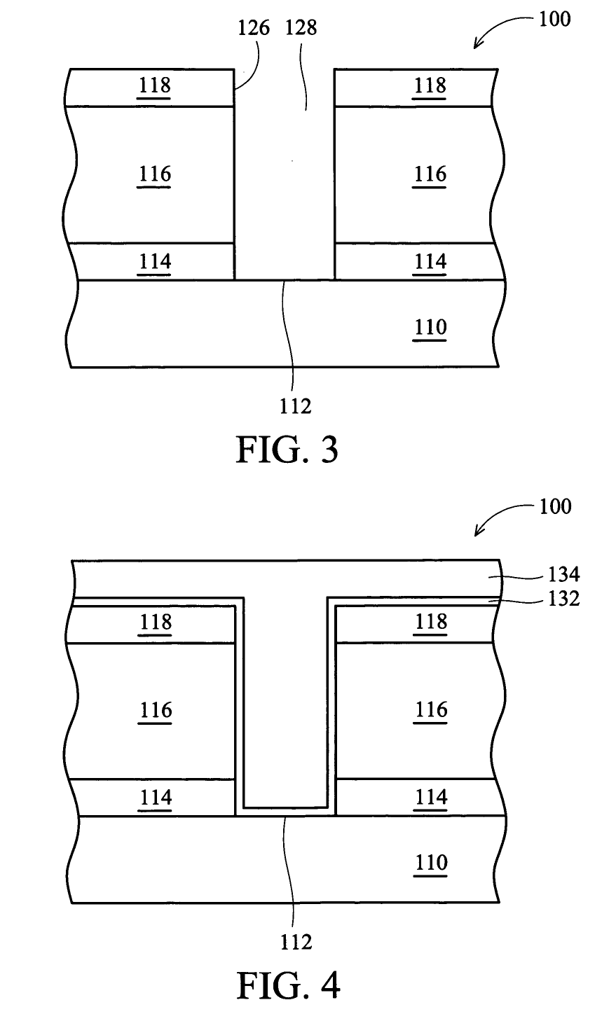

As shown in FIG. 3, an etching process, such as an anisotropic etching process, is performed along the first opening 126 to form a contact hole 128 in the dielectric layer 116 and the etching stop layer 114. In an embodiment of the invention, a depth and operation time of the etching process is precisely controlled by the etching stop layer to expose the first conductive area 112 without damaging the first conductive area 112.

As shown in FIG. 4, a barrier layer 132 comprising a conductive material is formed on a bottom and sidewalls of the contact hole 118 for stopping or hindering metal diffusion. In an embodiment of the invention, the barrier layer 132 comprises Ta, TaN, Ti, TiN, or a combination thereof.

A first conductive layer 134 is then formed on the barrier layer 132 and filled into the contact hole 118. The first conductive layer 134 is electrically connected to the first conductive area 112 through the conductive barrier layer 132. In an embodiment of the invention, at least one metal seed layer (not shown) is first formed on the barrier layer 132. The first conductive layer 134 is then formed on the metal seed layer. The first conductive layer 134 comprises copper (Cu), and can be formed by plasma vapor deposition (PVD), chemical vapor deposition (CVD), atomic layer deposition (ALD), or electro chemical process (ECP).

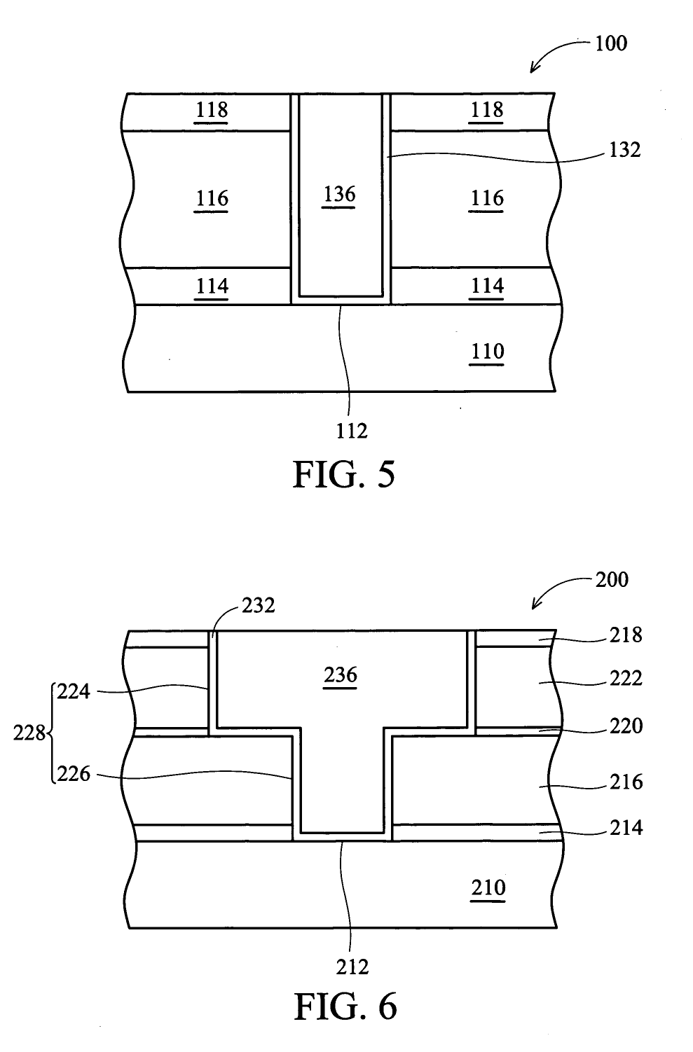

As shown in FIG. 5, a chemical mechanical polishing (CMP) process is performed by using the DARC layer 118 as a CMP stop layer to remove the excess first conductive layer 132 over a top surface of the DARC layer 118 and to form a contact plug 136. The DARC layer 118 serves as a CMP stop layer during the CMP process. As previously mentioned, the DARC layer 118 has sufficient hardness to prevent damage to a top surface of the contact plug 136. The height of the top surface of the DARC layer 118 is substantially equal to that of the contact plug 136.

Thereafter, another etching stop layer and an additional electric device having a second conductive area can be formed thereon according to the previously mentioned steps as shown in FIGS. 1-5. The second conductive area is electrically connected to the first conductive area 112 through the contact plug 136 to form a multi-layer interconnect structure.

FIG. 6 is a schematic diagram of another embodiment of a semiconductor device 200. As shown in FIG. 6, the semiconductor device 200 is basically the same as the semiconductor device 100 in the previous embodiment except the dual damascene structure 236. Thus, the subsequent description will focus on the fabrication procedure of the dual damascene structure 236 and the other parts are simplified.

According to an embodiment of a fabrication method of the semiconductor device 200, a substrate 110 with a conductive area 212 is first provided. A first etching stop layer 214, a first dielectric layer 216, a second etching stop layer 220, a second dielectric layer 222, and a DARC layer 218 are formed on the substrate 110 in sequence. A patterning process is then performed to form a dual damascene opening 228 comprising a via portion 226 in the first dielectric layer 216 and a trench portion 224 in a second dielectric layer 222 to expose the conductive area 212. In an embodiment of the invention, the patterning process is a via first process in which a via portion 226 is first formed prior to a trench portion 224. However, the patterning process can be performed by other ways, such as a trench first process in which the trench portion 224 is formed prior to the via portion 226. As mentioned previously, the DARC layer 218 can reduce a reflective rate of the semiconductor device 200 and improve the lithography accuracy during the pattering process.

After the dual damascene opening 228 is formed, a barrier layer 232 is formed inside the dual damascene opening 228 and a conductive layer, such as Cu, is then filled into the dual damascene opening 228. A CMP process is performed by using the DARC layer 218 as a CMP stop layer to remove the excess conductive layer over a top surface of the DARC layer 218 and to form a dual damascene structure 236. The DARC layer 218 serves as a CMP stop layer during the CMP process. As previously mentioned, the DARC layer 218 has sufficient hardness to prevent damage to a top surface of the dual damascene structure 236.

Thereafter, another etching stop layer and an additional electric device having a second conductive area can be formed thereon according to the previously mentioned steps. The second conductive area is electrically connected to the first conductive area 212 through the dual damascene structure 236 to form a multi-layer interconnect structure.

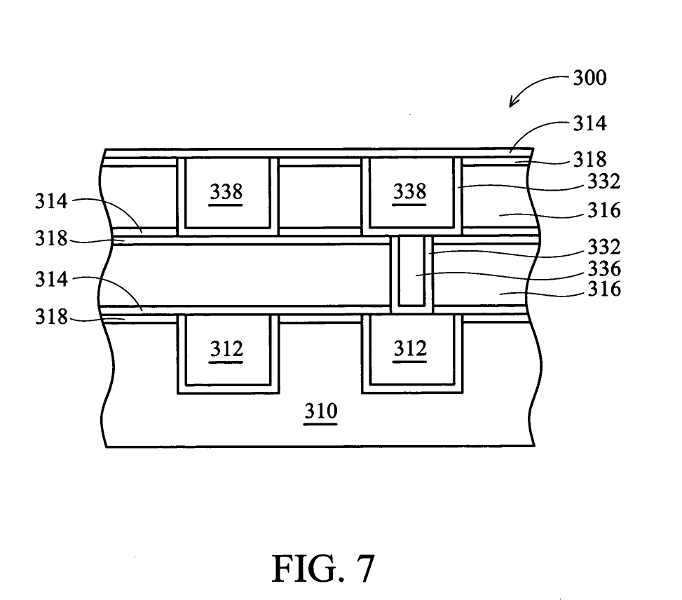

FIG. 7 is a schematic diagram of another embodiment of a semiconductor device 300. As shown in FIG. 7, the semiconductor device 300 comprises a multi-layer interconnect structure having a first electronic device 312, a second electronic device 338, and a contact plug 336 therebetween to electrically connect the first electronic device 312 and the second electronic device 338. The multi-layer interconnect structure is formed in etching stop layers 314, dielectric layers 316, and DARC layers 318 formed on a substrate 310. A fabricating method of the semiconductor device 300 is omitted here since it should be obvious to one skilled in the art after reading the methods in the previous embodiment.

According to embodiments of the invention, the DARC layer has characteristics of a high etching selectivity over the beneath dielectric layer, a good adhesion and excellent CMP selectivity, a good adhesion with the next etching stop layer, excellent moisture resistance, and a low dielectric constant. Thus, the DARC layer not only functions as an anti-reflective layer but also serves as a hard mask for etching and a cap layer and CMP stop layer for the CMP process.

In comparison with the related art, the invention provides a DARC layer with multiple functions to simplify the fabrication process and reduce manufacturing costs. In addition, the DARC layer further has advantages of improved adhesion between the dielectric layer and the etching stop layer, increased the moisture resistance, and reduced dielectric constant between electronic devices. Thus, reliability and electrical performance of the semiconductor device can be improved in advance.

While the invention has been described by way of example and in terms of preferred embodiment, it is to be understood that the invention is not limited thereto.

What is claimed is:

1. A method of fabricating a semiconductor device, comprising:
providing a substrate;
forming at least one dielectric layer comprising a low dielectric constant material on the substrate;
forming a carbon-containing dielectric anti-reflective coating (DARC) layer on the dielectric layer;
patterning the DARC layer to form a first opening in the carbon-containing DARC layer;
forming a hole in the dielectric layer along the first opening to expose the substrate;
forming a first conductive layer on the carbon-containing DARC layer and filling the hole; and
performing a chemical mechanic polish (CMP) process by using the carbon-containing DARC layer as a CMP stop layer to remove the first conductive layer above a top surface of the DARC layer.

2. The method as claimed in claim 1 wherein the carbon-containing DARC layer is a nitrogen-free DARC (NFDARC) layer.

3. The method as claimed in claim 1 further comprising forming a second electric device with a second conductive area above the first conductive layer, the second conductive area electrically connected to the first conductive layer.

4. The method as claimed in claim 1 further comprising forming a barrier layer on a bottom and sidewalls of the hole before the first conductive layer is formed.

5. The method as claimed in claim 1 wherein the carbon-containing DARC layer comprises SiC, SiCO, SiCO:H, or a combination thereof.

6. The method as claimed in claim 1 wherein the dielectric layer has a dielectric constant below 3.

7. The method as claimed in claim 1 wherein an etching selectivity between the carbon-containing DARC layer and the dielectric layer is larger than 5.

8. A semiconductor device comprising:
a substrate with a first conductive area;
at least one dielectric layer comprising a low dielectric constant material on the substrate;
a carbon-containing dielectric anti-reflective coating (DARC) layer disposed on the dielectric layer for reducing a reflective rate of the substrate;
a contact hole extended through the carbon-containing DARC layer and the dielectric layer to the first conductive area; and
a contact plug comprising of a first conductive layer disposed in the contact hole and electrically connected to the first conductive area.

9. The semiconductor device as claimed in claim 8 further comprising an electronic device having a second conductive area electrically connected to the first conductive area through the contact plug.

10. The semiconductor device as claimed in claim 8 further comprising a barrier layer surrounding a bottom and sidewalls of the contact hole, the contact plug disposed inside the barrier layer.

11. The semiconductor device as claimed in claim 8 wherein the DARC layer comprises SiC, SiCO, SiCO:H, or a combination thereof.

12. The method as claimed in claim 8 wherein the dielectric layer has a dielectric constant below 3.

13. The semiconductor device as claimed in claim 8 wherein an etching selectivity between the carbon-containing DARC layer and the dielectric layer is larger than 5.

14. The semiconductor device as claimed in claim 8 wherein the carbon-containing DARC layer has a dielectric constant of 3 to 5.

15. The semiconductor device as claimed in claim 8 wherein the carbon-containing DARC layer is a nitrogen free dielectric anti-reflective coating (NFDARC) layer.

16. A semiconductor device comprising:
a substrate with a first conductive area;
a first dielectric layer comprising a low dielectric constant material on the substrate;
a carbon-containing and nitrogen-free dielectric anti-reflective coating (DARC) layer disposed on the first dielectric layer for reducing a reflective rate of the semiconductor device;
an opening extending through the DARC layer and the first dielectric layer to expose the first conductive area; and
a conductive layer disposed in the opening and electrically connected to the first conductive area.

17. The semiconductor device as claimed in claim 16 further comprising an electronic device having a second conductive area electrically connected to the first conductive area through the conductive layer.

18. The semiconductor device as claimed in claim 16 further comprising a barrier layer surrounding a bottom and sidewalls of the opening, the conductive layer disposed inside the barrier layer.

19. The semiconductor device as claimed in claim 16 further comprising a first etching stop layer interposed between the substrate and the first dielectric layer.

20. The semiconductor device as claimed in claim 16, wherein a height of a top surface of the conductive layer is substantially equal to that of the DARC layer.
